(19) United States
(12) Patent Application Publication
(10) Pub. No.: US 2010/0252833 A1
(43) Pub. Date: Oct. 7, 2010

(54) THIN FILM TRANSISTOR DEVICES HAVING TRANSISTORS WITH DIFFERENT ELECTRICAL CHARACTERISTICS AND METHOD FOR FABRICATING THE SAME

(75) Inventors: Yu-Chung Liu, Kaohsiung City (TW); Te-Yu Lee, Zhubei City (TW); Mei-Ling Chang, Miaoli County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: TPO DISPLAYS CORP., Miao-Li Country (TW)

(21) Appl. No.: 12/725,545

(22) Filed: Mar. 17, 2010

(30) Foreign Application Priority Data
Apr. 7, 2009 (TW) 98111464

(51) Int. Cl. H01L 33/16; H01L 21/336

(52) U.S. Cl. 257/59; 438/34; 257/E21.414; 257/E33.004

(57) ABSTRACT

A system for displaying images is provided. The system includes a thin film transistor (TFT) device comprising a substrate having a pixel region, a driving thin film transistor and a switching thin film transistor. The driving thin film transistor and the switching thin film transistor are disposed on the substrate and in the pixel region. The driving thin film transistor includes a polysilicon active layer and the switching thin film transistor includes an amorphous silicon active layer. A method for fabricating the system for displaying images including the TFT device is also disclosed.

### CROSS REFERENCE TO RELATED APPLICATIONS

This Application claims priority of Taiwan Patent Application No. 098111464, filed on Apr. 7, 2009, the entirety of which is incorporated by reference herein.

### BACKGROUND OF THE INVENTION

1. Field of the Invention

The invention relates to flat panel display (FPD) technology, and in particular to an organic light-emitting diode (OLED) display comprising a thin film transistor (TFT) device having transistors with different electrical characteristics and a method for fabricating the same.

2. Description of the Related Art

The demand for active-matrix flat panel displays, such as active matrix organic light emitting device (AMOLED) displays, has increased rapidly in recent years. AMOLED displays typically employ thin film transistors (TFTs) as a switching element and as a driving element for a light-emitting device in a pixel region. Additionally, AMOLED displays also employ a complementary metal oxide semiconductor (CMOS) circuit composed of TFTs in a peripheral circuit region.

Such elements are classified as amorphous silicon (a-Si) TFTs and polysilicon TFTs according to the active layer materials used. The fabrication of a-Si TFTs has the advantages of simple processes and low manufacturing costs. However, the active layers of a-Si TFTs deteriorate easily and therefore are unsuitable to serve as driving elements for light-emitting devices. Currently, polysilicon TFTs are formed by low temperature polysilicon (LTPS) fabrication processes and have the advantages of high carrier mobility, high driving-circuit integration and low leakage current. For LTPS-TFT fabrication, however, the active layers of polysilicon TFTs are formed by laser crystallization and thus, have a drawback of high manufacturing costs. Moreover, since the laser output energy is non-uniform, the driving current of each TFT for driving the OLED varies and thus, induces mura defects in displays.

Additionally, in AMOLED displays, the electrical characteristic of the switching TFTs in the pixel region are different from that of the driving TFTs in the pixel region. For example, it is desirable to design the switching TFTs with high sub-threshold swing and low threshold voltage to increase gray scale and extend OLED lifespan. However, it is difficult to fabricate TFTs with different electrical characteristics with the LTPS fabrication process.

### BRIEF SUMMARY OF THE INVENTION

A detailed description is given in the following embodiments with reference to the accompanying drawings. A system for displaying images and a method for fabricating the same are provided. An exemplary embodiment of a system for displaying images comprises a thin film transistor (TFT) device comprising a thin film transistor (TFT) device comprising a substrate having a pixel region, a driving thin film transistor and a switching thin film transistor. The driving thin film transistor and the switching thin film transistor are disposed on the substrate and in the pixel region. The driving thin film transistor includes a polysilicon active layer and the switching thin film transistor includes an amorphous silicon active layer.

An embodiment of a method for fabricating a system for displaying images is provided, wherein the system comprises a thin film transistor device, and the method comprises providing a substrate having a pixel region. A driving thin film transistor and a switching thin film transistor are formed on the substrate and in the pixel region, wherein the driving thin film transistor comprises a polysilicon active layer and the switching thin film transistor comprises an amorphous silicon active layer.

### BRIEF DESCRIPTION OF DRAWINGS

The invention can be more fully understood by reading the subsequent detailed description and examples with references made to the accompanying drawings, wherein:

FIG. 1 is a plan view of an active matrix organic light emitting device display;

FIG. 2 is a circuit diagram of a pixel unit in FIG. 1.

FIGS. 3A to 3H are cross section views of an embodiment of a method for fabricating a system for displaying images including a thin film transistor device according to the invention; and

FIG. 4 schematically shows another embodiment of a system for displaying images.

### DETAILED DESCRIPTION OF INVENTION

The following description is of the best-contemplated mode of carrying out the invention. This description is provided for the purpose of illustrating the general principles of the invention and should not be taken in a limiting sense. The scope of the invention is best determined by reference to the appended claims.

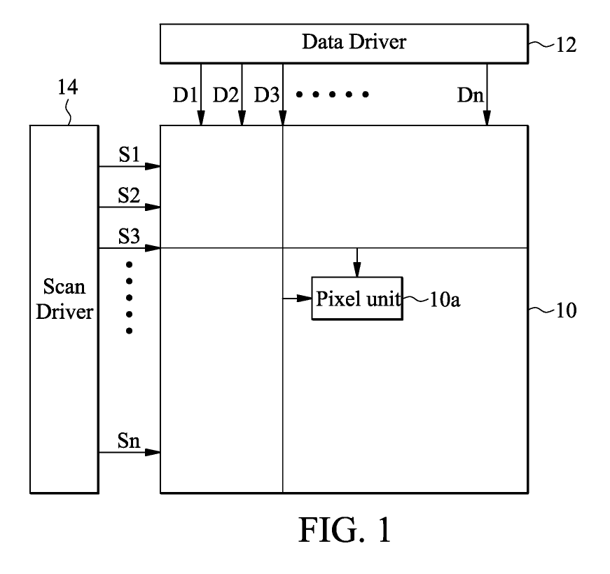

Referring to FIG. 1, which is a plan view of an active matrix organic light emitting device (AMOLED) display. The AMOLED display comprises a display panel 10, a data driver 12, and a scan driver 14. The display panel 10 includes a plurality of pixel units and only one pixel unit 10a is depicted in order to simplify the diagram. The data driver 12 may comprise a plurality of data lines D1 to Dn, and the scan driver 14 may include a plurality of scan lines S1 to Sn. Each pixel unit 10a is connected to one data line and one scan line (e.g. the data line D3 and the scan line S3) so as to be arranged as a matrix.

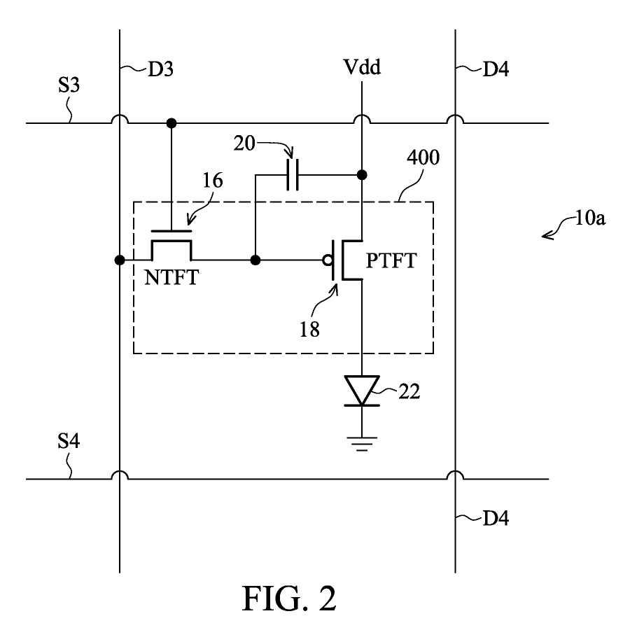

Referring to FIG. 2, which illustrates a circuit diagram of a pixel unit 10a in FIG. 1. The pixel unit 10a comprises a light-emitting device 22 such as an organic light-emitting diode, a thin film transistor device 400, and a storage capacitor 20 for storing image data. The thin film transistor device 400 comprises a driving TFT 18 for driving the light-emitting device 22, and a switching TFT 16 for switching the turn on/off states of the pixel unit 10a. In the embodiment, the driving TFT 18 for driving the light-emitting device 22 is typically a P-type TFT (PTFT) and the switching TFT 16 is typically an N-type TFT (NTFT). The switching TFT 16 has a gate connected to the corresponding scan line S3, a drain connected to the corresponding data line D3, and a source connected between one terminal of the storage capacitor 20 and the gate of the driving TFT 18. Another terminal of the storage capacitor 20 is connected to the source of the driving TFT 18, which is connected to the power source Vdd. The drain of the driving TFT 18 is connected to the light-emitting device 22.

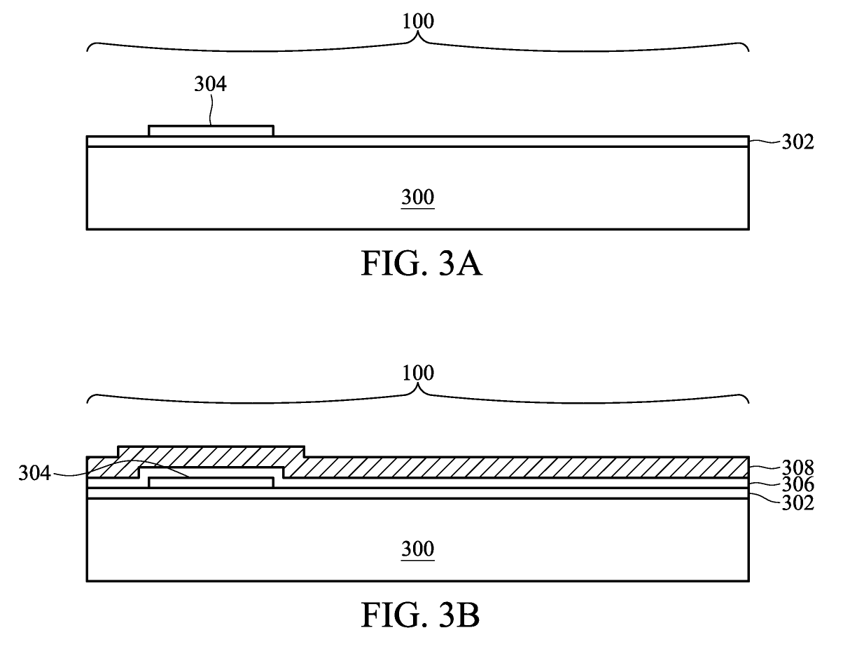

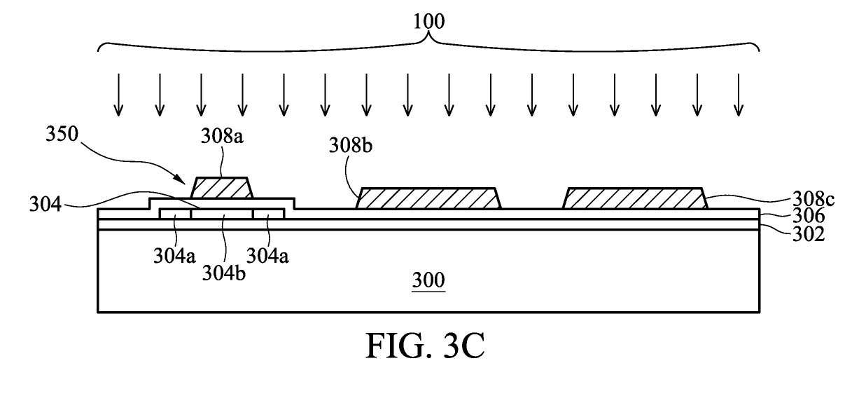

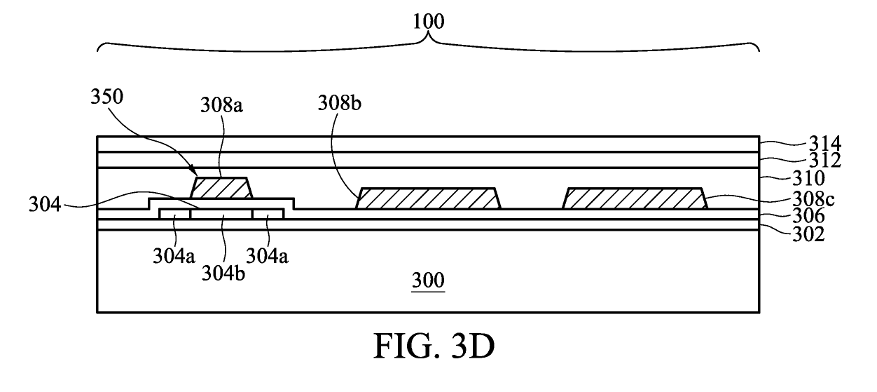

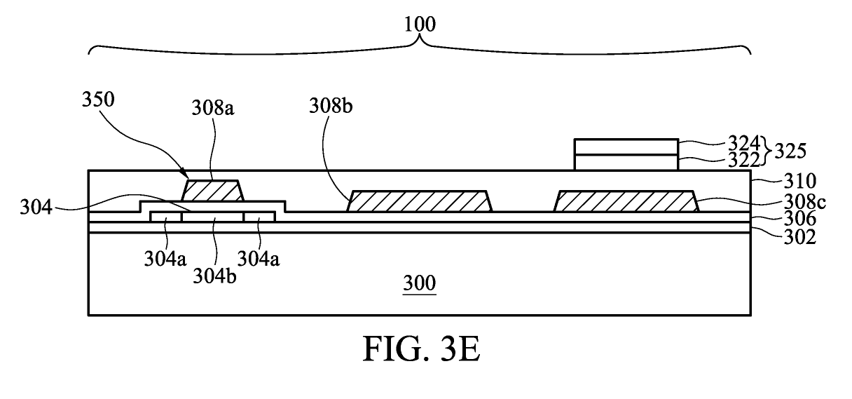

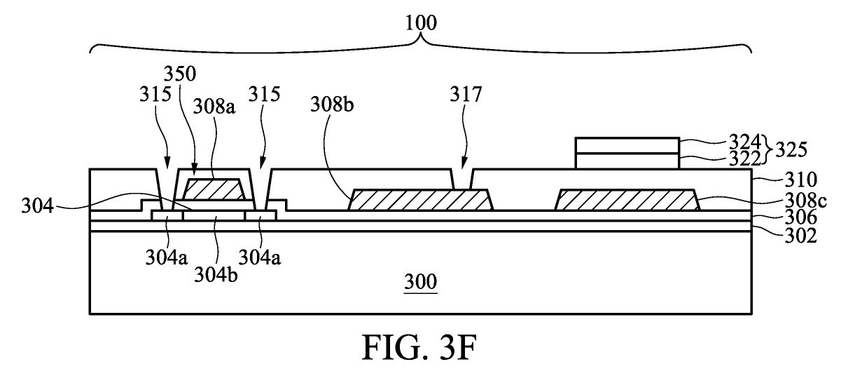

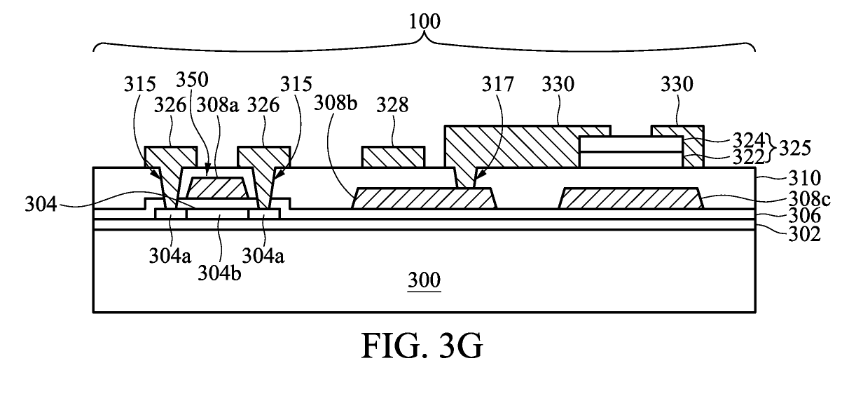

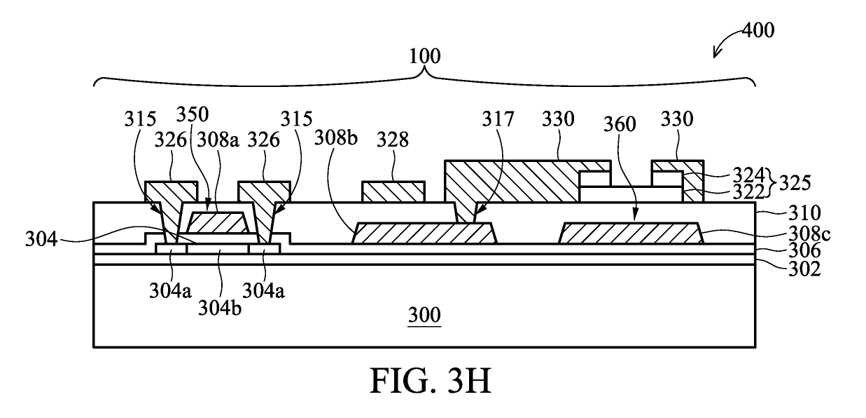

Systems for displaying images and fabrication methods for same are provided. FIG. 3H illustrates an exemplary embodiment of such a system. Specifically, the system incorporates a thin film transistor (TFT) device 400. In the embodiment, a glass substrate is utilized for fabrication of the switching TFTs (e.g. NTFTs) in the pixel regions and the driving TFTs (e.g. PTFTs) in the pixel regions.

The TFT device 400 comprises a substrate 300 having a pixel region 100. A buffer layer 302, which may comprise silicon oxide, silicon nitride, or a combination thereof, may be optionally disposed on the substrate 300 to serve as an adhesion layer or a contamination barrier layer between the substrate 300 and the subsequent active layer.

A driving TFT 350 is disposed in the pixel region 100 and on the buffer layer 302 above the substrate 300 for driving a light-emitting element (not shown), such as an organic light-emitting diode (OLED). The driving TFT 350 has a top-gate structure and comprises a polysilicon active layer 304, a first insulating layer 306 covering the polysilicon active layer 304 to serve as a gate dielectric layer, and a first gate electrode 308a above the polysilicon active layer 304. The polysilicon active layer 304 may comprise a channel region 304b and a pair of source/drain regions 304a separated by the channel region 304b. A pair of first source/drain electrode 326 on both sides of the first gate electrode 308a is electrically connected to the pair of the source/drain regions 304a, respectively.

A switching TFT 360 is disposed in the pixel region 100 and on the buffer layer 302 above the substrate 300 for switching the turn on/off states of the pixel. The Switching TFT 360 has a bottom-gate structure and comprises a second gate electrode 308c, a second insulating layer 310 covering the second gate electrode 308c to serve as a gate dielectric layer, and an amorphous silicon active layer 325 above second gate electrode 308c. The amorphous silicon active layer 325 may comprise a pair of source/drain layer 324 and a channel layer 322 between the pair of source/drain layer 324 and the second gate electrode 308c. A pair of second source/drain electrode 330 on both sides of the amorphous silicon active layer 325 contacts the pair of source/drain layer 324 for electrical connection.

A storage capacitor is disposed in the pixel region 100 and on the buffer layer 302 above the substrate 300, and is electrically connected to the switching TFT 360 through one of the pair of second source/drain electrode 330. The storage capacitor may comprise a lower electrode 308b, an upper electrode 328, and the second insulating layer 310 between the lower electrode 308b and the upper electrode 328 to serve as a capacitor dielectric layer. In the embodiment, the first gate electrode 308a, the second gate electrode 308c, and the lower electrode 308b may be formed of the same metal layer, and also the pair of first source/drain electrodes 326, the pair of the second source/drain electrodes 330, and the upper electrode 328 may be formed of the same metal layer.

Referring to FIGS. 3A to 3H, which illustrate an embodiment of a method for fabricating a system for displaying images incorporating a thin film transistor device 400. In FIG. 3A, a substrate 300 having a pixel region 100 is provided. The substrate 300 may comprise glass, quartz, or other transparent materials. Next, a buffer layer 302 may be optionally formed on the substrate 300. An amorphous silicon layer (not shown) is subsequently formed on the buffer layer 302 and then crystallization and patterning processes are successively performed to form a polysilicon active layer 304. In the embodiment, the polysilicon active layer 304 is formed by performing the crystallization process such as a non-laser crystallization process. For example, the non-laser crystallization process may comprise solid phase crystallization (SPC), metal induced crystallization (MIC), metal induced lateral crystallization (MILC), field enhanced metal induced lateral crystallization (FE-MILC), or field enhanced rapid thermal annealing process. It is noted that the various crystallization processes mentioned above are exemplary embodiments and the invention is not limited thereto.

In FIG. 3B, a first insulating layer 306 and a metal layer 308 are successively formed in the pixel region 100 and on the substrate 300, and covers the polysilicon active layer 304, in which the first insulating layer 306 is used as a gate dielectric layer and the metal layer 308 is used for definition of gate electrodes and an lower electrode of a capacitor. The first insulating layer 306 may comprise silicon oxide, silicon nitride, or other gate dielectric materials well known in the art and the metal layer 308 may comprise molybdenum (Mo), an alloy thereof, or other metal gate materials well known in the art.

In FIG. 3C, the metal layer 308 is patterned to form first electrode 308a, a second gate electrode 308c, and a lower electrode 308b, respectively, in the pixel region 100 and on the first insulating layer 306, in which the first gate electrode 308a is on the first insulating layer 306 above the polysilicon active layer 304. Thereafter, a heavy ion implantation process 309 is performed on the polysilicon active layer 304 using the first gate electrode 308a as an implant mask to form channel region 304b and source/drain regions 304a, such as P-type source/drain regions, in the polysilicon active layer 304. Here, the polysilicon active layer 304, the first insulating layer 306, and the first gate electrode 308a form the driving TFT 350.

In FIG. 3D, a second insulating layer 310, an amorphous silicon layer 312, and a doped amorphous silicon layer 314 (such as an N-type doped amorphous silicon layer) are successively formed on the first insulating layer 306 and covers the first gate electrode 308a, the second gate electrode 308c, and the lower electrode 308b. The second insulating layer 310 is used as a both gate dielectric layer and a capacitor dielectric layer. Moreover, the second insulating layer 310 may also comprise silicon oxide, silicon nitride, or other gate dielectric materials well known in the art.

In FIG. 3E, the doped amorphous silicon layer 314 and the underlying amorphous silicon layer 312 are successively patterned by a conventional lithography and etching processes to form an amorphous silicon active layer 325 on the second insulating layer 310 above the second gate electrode 308c. In the embodiment, the amorphous silicon active layer 325 may comprise a source/drain layer 324 formed by the doped amorphous silicon layer 314, and a channel layer 322 between the source/drain layers 324 and the second gate electrode 308c.

In FIG. 3F, openings 315 are formed in the second insulating layer 310 and the underlying first insulating layer 306 on both sides of the first gate electrode 308a by a conventional lithography and etching processes to expose the source/drain regions 304a. Simultaneously, an opening 317 is formed in the second insulating layer 310 above the lower electrode 308b to expose a portion of the lower electrode 308b.

In FIG. 3G, a metal layer (not shown) is formed on the second insulating layer 310, fills the openings 315 and 317, and covers the amorphous silicon active layer 325. In the embodiment, the metal layer may comprise aluminum (Al), molybdenum (Mo), titanium (Ti), or a combination thereof. The metal layer 320 is subsequently patterned by a conventional lithography and etching processes to form a pair of first source/drain electrodes 326, an upper electrode 328, and a pair of second source/drain electrodes 330 on the second insulating layer 310, respectively. The pair of first source/drain electrodes 326 is substantially on both sides of the first gate electrode 308a and is electrically connected to the corresponding source/drain regions 304a through the openings 315 in the second insulating layer 310. A storage capacitor is constructed by the upper electrode 328, the underlying second insulating layer 310 and the underlying lower electrode 308b. The pair of second source/drain electrodes 330 extends to the top surface of the amorphous silicon active layer 325 to be electrically connected thereto and to expose a portion of the source/drain layer 324. Moreover, one of the pair of the second source/drain electrode 330 is electrically connected to the lower electrode 308b of the storage capacitor through the opening 317 in the second insulating layer 310.

In FIG. 3H, the exposed portion of the source/drain layer 324 are removed to form a pair of separated source/drain layers 324 and expose a portion of the channel layer 322. Here, a switching TFT 360 is constructed by the amorphous silicon active layer 325 including the pair of separated source/drain layers 324 and the channel layer 322, the underlying second insulating layer 310, and the second gate electrode 308c.

According to the embodiment, since the active layer of the driving TFT is formed by a non-laser crystallization process, mura defects in the display can be prevented. Moreover, compared with the conventional driving and switching TFTs formed by the LTPS fabrication process, since the active layer of the switching TFT is formed of amorphous silicon and the active layer of the driving TFT is formed by a non-laser crystallization process, the electrical characteristic of the driving TFT can be different from that of the switching TFT and manufacturing costs can be reduced.

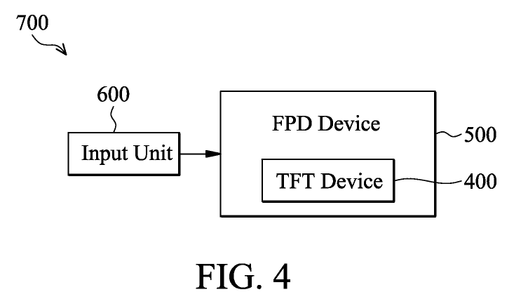

FIG. 4 schematically shows another embodiment of a system for displaying images which, in this case, is implemented as a flat panel display (FPD) device 500 or an electronic device 700 such as a laptop computer, a mobile phone, a digital camera, a personal digital assistant (PDA), a desktop computer, a television, a car display or a portable DVD player. The described TFT device 400 can be incorporated into the flat panel display device 500 that can be an OLED device. In some embodiments, the TFT device 400 can be incorporated into the electronic device 700. As shown in FIG. 4, the electronic device 700 comprises the FPD device 500 and an input unit 600. Moreover, the input unit 600 is coupled to the FPD device 500 and operative to provide input signals (e.g. image signals) to the FPD device 500 to generate images.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A system for displaying images, comprising:
a thin film transistor device, comprising:
a substrate having a pixel region; and
a driving thin film transistor and a switching thin film transistor disposed on the substrate and in the pixel region, wherein the driving thin film transistor comprises a polysilicon active layer and the switching thin film transistor comprises an amorphous silicon active layer.

2. The system of claim 1, wherein the driving thin film transistor further comprises a first gate electrode disposed above the polysilicon active layer and a second gate electrode disposed under the amorphous silicon active layer.

3. The system of claim 2, wherein the driving thin film transistor further comprises a first source/drain electrode electrically connected to the polysilicon active layer and a second source/drain electrode electrically connected to the amorphous silicon active layer, wherein the first and second source/drain electrodes are formed of the same metal layer.

4. The system as claimed in claim 3, wherein the amorphous silicon active layer further comprises:
a source/drain layer contacting with the second source/drain electrode; and
a channel layer disposed between the source/drain layer and the second gate electrode.

5. The system of claim 2, wherein the first and second gate electrodes are formed of the same metal layer.

6. The system of claim 1, further comprising a buffer layer covering the substrate, wherein the buffer layer is selected from the group consisting of silicon oxide, silicon nitride or a combination thereof.

7. The system of claim 1, further comprising a flat panel display device comprising the thin film transistor device, wherein the flat panel display device is an organic light-emitting diode display.

8. The system as claimed in claim 7, further comprising an electronic device comprising:
the flat panel display device; and
an input unit coupled to the flat panel display device and operative to provide input singles to the flat panel display device, such that the flat panel display device displays images.

9. The system of claim 8, wherein the electronic device is a laptop computer, a mobile phone, a digital camera, a personal digital assistant, a desktop computer, a television, a car display or a portable DVD player.

10. A method for fabricating a system for displaying images, wherein the system comprises a thin film transistor device, comprising:
providing a substrate having a pixel region; and
forming a driving thin film transistor and a switching thin film transistor on the substrate and in the pixel region,
wherein the driving thin film transistor comprises a polysilicon active layer and the switching thin film transistor comprises an amorphous silicon active layer.

11. The method of claim 10, wherein the driving thin film transistor further comprises a first gate electrode disposed above the polysilicon active layer and a second gate electrode disposed under the amorphous silicon active layer, wherein the first and second gate electrodes are formed of the same metal layer.

12. The method of claim 10, wherein the formation of the driving and switching thin film transistors comprises:
forming the polysilicon active layer in the pixel region of the substrate;
covering a first insulating layer over the polysilicon active layer and the substrate;
forming a first gate electrode and a second gate electrode on the first insulating layer, wherein the first gate electrode is above the polysilicon active layer;
covering a second insulating layer over the first and second gate electrodes;
forming the amorphous silicon active layer on the second insulating layer above the second gate electrode; and
forming a first source/drain electrode and a second source/drain electrode above the second insulating layer and electrically connected to the polysilicon active layer and the amorphous silicon active layer.

13. The method of claim 12, wherein the amorphous silicon active layer further comprises:
a source/drain layer contacting the second source/drain electrode; and
a channel layer disposed between the source/drain layer and the second gate electrode.

14. The method of claim 12, further comprising forming a buffer layer on the substrate prior to formation of the polysilicon active layer, wherein the buffer layer comprises silicon oxide, silicon nitride or a combination thereof.

15. The method of claim 12, wherein the polysilicon active layer is formed by a non-laser crystallization process.

16. The method of claim 15, wherein the non-laser crystallization process comprises a solid phase crystallization, metal induced crystallization, metal induced lateral crystallization, field enhanced metal induced lateral crystallization, or field enhanced rapid thermal annealing process.
